(19) United States
(12) Patent Application Publication
(10) Pub. No.: US 2026/0051646 A1
(43) Pub. Date: Feb. 19, 2026

(54) BROADBAND SUB-TERAHERTZ METHOD FOR INTERCONNECTING DIES AND APPLICATIONS THEREOF

(71) Applicant: Qorvo US, Inc., Greensboro, NC (US)

(72) Inventor: Assaf Aviv Haviv, Frisco, TX (US)

(21) Appl. No.: 19/237,125

(22) Filed: Jun. 13, 2025

Related U.S. Application Data
(60) Provisional application No. 63/684,026, filed on Aug. 16, 2024.
(60) Provisional application No. 63/717,041, filed on Nov. 6, 2024.

(51) Int. Cl. H01P 3/08; H01L 23/66

(52) U.S. Cl. CPC H01P 3/081; H01L 23/66; H01L 2223/6627

(57) ABSTRACT

Aspects of the disclosure advantageously provide circuits and methods using the same in signal transmission. In some embodiments, a circuit includes a signal transmission line configured to transmit a signal between two ports, the signal transmission line comprising a first transmit portion coupled to a second transmit portion via a first interconnect stage and the second transmit portion coupled to a third transmit portion via a second interconnect stage, wherein the second transmit portion comprises a quarter wavelength transmission line having a length that is a quarter of a wavelength of the signal being transmitted between the two ports. In some embodiments, the first interconnect stage and the second interconnect stage each comprise a contact pad having identical, or substantially similar, shape and size.

### CROSS REFERENCE(S)

The application claims the benefit of U.S. Provisional Application No. 63/717,041, filed Nov. 6, 2024, and U.S. Provisional Application No. 63/684,026, filed Aug. 16, 2024, both of which are hereby expressly incorporated by reference herein in its entirety.

### TECHNICAL FIELD

The present disclosure relates generally to semiconductor manufacturing methodologies and related implementations, and in particular, relates to systems and methods for preparing interconnects for broadband sub-terahertz dies.

### BACKGROUND

Advanced semiconductor electronics are typically assembled using cutting-edge manufacturing techniques. The current approaches to preparing interconnects or transmission lines for device-to-device communications, for example, involve connecting an input line to the top of a die/interposer through a via, which interfaces with a soldered pad on a laminate, in order to create a relatively large structure that interacts with surrounding grounds. This currently used approach in industry inevitably introduces known issues, namely, parasitic effects at the material interfaces that degrade performance.

To address these issues, existing methods typically increase clearances between via pads to the ground and use impedance matching techniques, which improve performance, albeit only within a limited and narrow frequency band. Thus, there is also a need for a new configuration that enable impedance matching at interconnects as well as consistently delivering excellent performance across a broad frequency spectrum.

### SUMMARY

Embodiments of the present disclosure include advanced semiconductor manufacturing methodologies with innovative implementation of interconnects for broadband sub-terahertz dies. Aspects of the disclosure advantageously provide a circuit comprising such interconnects and one or more methods of using the circuit in signal transmission in wireless communications or radar systems.

In an exemplary aspect, a circuit is provided. The circuit includes a signal transmission line that includes one or more interconnects (also referred to herein as interconnect stages). The signal transmission line is configured to transmit a signal between two ports (e.g., an input and an output, or a first component and a second component), the signal transmission line comprising a first transmit portion coupled to a second transmit portion via a first interconnect stage and the second transmit portion coupled to a third transmit portion via a second interconnect stage, wherein the second transmit portion comprises a quarter wavelength transmission line having a length that is a quarter of a wavelength of the signal being transmitted between the two ports.

In one or more embodiments, the first transmit portion, the second transmit portion, and the third transmit portion are formed on distinct and isolated surface layers, or on different surfaces. In one or more embodiments, the first transmit portion is formed on a first surface layer, the second transmit portion is formed on a second surface layer different from the first surface layer, and the third transmit portion is formed on a third surface layer that is different from the first surface layer and the second surface layer.

In one or more embodiments, the first interconnect stage and the second interconnect stage each comprise a contact pad having identical, or substantially similar, shape and size. In one or more embodiments, the first interconnect stage and the second interconnect stage each comprise a contact pad having an identical, or substantially similar, parasitic capacitance value to one another.

In one or more embodiments, the first interconnect stage includes a vertical interconnect that connects the first surface layer and the second surface layer. In one or more embodiments, the second interconnect stage includes a via hole that connects the second surface layer and the third surface layer. In one or more embodiments, the second surface layer and the third surface layer are surface layers of a film and the via hole is formed through a thickness of the film. In one or more embodiments, the film includes a thin film, a ceramic film, an organic film, a composite film, a laminate, silicon carbide, glass, a solder, or a combination thereof.

In an exemplary aspect, an electronic device is provided. The electronic device includes a signal transmission line that includes one or more interconnects (also referred to herein as interconnect stages). The signal transmission line of the electronic device may be configured to transmit a signal between two ports (e.g., an input and an output), the signal transmission line comprising a first transmit portion coupled to a second transmit portion via a first contact pad and the second transmit portion coupled to a third transmit portion via a second contact pad, wherein the first contact pad and the second contact pad have identical, or substantially similar, shape and size. In one or more embodiments, the first contact pad and the second contact pad have identical, or substantially similar, parasitic capacitance values.

In one or more embodiments of the electronic device, the second transmit portion comprises a quarter wavelength transmission line having a length that is a quarter of a wavelength of the signal being transmitted between the two ports. In one or more embodiments, the first transmit portion, the second transmit portion, and the third transmit portion are formed on distinct and isolated surface layers, or on different surfaces. In one or more embodiments, the first contact pad further comprises a vertical interconnect that connects the first surface layer and the second surface layer.

In one or more embodiments, the second contact pad further comprises a via hole that connects the second surface layer and the third surface layer. In one or more embodiments, the the second surface layer and the third surface layer are surface layers of a film and the via hole is formed through a thickness of the film. In one or more embodiments, the film includes a thin film, a ceramic film, an organic film, a composite film, a laminate, silicon carbide, glass, a solder, or a combination thereof.

In an exemplary aspect, a method for transmitting a signal is provided. The method includes transmitting the signal via a signal transmission line configured to transmit signals between two ports, wherein the signal transmission line comprises a first transmit portion coupled to a second transmit portion via a first interconnect stage and the second transmit portion coupled to a third transmit portion via a second interconnect stage, and wherein the second transmit portion comprises a quarter wavelength transmission line having a length that is a quarter of a wavelength of the signal being transmitted between the two ports.

In one or more embodiments, the two ports are within a circuit. In one or more embodiments, the two ports reside on two separate circuits/electronic components and the signal transmission line is configured for transmitting the signal between the two separate circuits/electronic components. In one or more embodiments, the first transmit portion, the second transmit portion, and the third transmit portion are formed on distinct and isolated surface layers, or on different surfaces. In one or more embodiments, the first interconnect stage and the second interconnect stage each comprise a contact pad having an identical, or substantially similar, parasitic capacitance value to one another. In one or more embodiments, the first interconnect stage includes a vertical interconnect that connects the first surface layer and the second surface layer. In one or more embodiments, the second interconnect stage includes a via hole that connects the second surface layer and the third surface layer. In one or more embodiments, the second interconnect stage is a via hole that connects the second surface layer and the third surface layer; the second surface layer and the third surface layer are surface layers of a film and the via hole is formed through a thickness of the film; and the film comprises a thin film, a ceramic film, an organic film, a composite film, a laminate, silicon carbide, glass, a solder, or a combination thereof.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates an example circuit comprising one or more interconnects, according to aspects of the present disclosure.

FIGS. 2A, 2B, and 2C illustrate an example circuit comprising one or more interconnects, according to aspects of the present disclosure.

FIGS. 3A, 3B, and 3C are plots showing simulation results of the example circuit shown in FIGS. 2A, 2B, and 2C, according to aspects of the present disclosure.

FIGS. 4A, 4B, and 4C are plots showing simulation results of the example circuit shown in FIGS. 2A, 2B, and 2C over a broader frequency range, according to aspects of the present disclosure.

FIGS. 5A and 5B illustrate an example circuit comprising one or more interconnects, according to aspects of the present disclosure.

FIGS. 6A, 6B, and 6C are plots showing simulation results of the example circuit shown in FIGS. 5A and 5B, according to aspects of the present disclosure.

FIGS. 7A, 7B, and 7C are plots showing simulation results of the example circuit shown in FIGS. 5A and 5B over a broader frequency range, according to aspects of the present disclosure.

FIG. 8 illustrates a method for using an example circuit, according to aspects of the present disclosure.

FIG. 9 illustrates an electronic device comprising an example circuit, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include advanced semiconductor manufacturing methodologies with innovative implementation of interconnects for broadband sub-terahertz dies. Aspects of the disclosure advantageously provide a circuit, an electronic device, an electronic component, or a transmission line comprising such interconnects and one or more methods of using the disclosed circuit, component, or transmission line for signal transmission. In accordance with one or more embodiments, the disclosed circuit, component, or transmission line may include interconnecting dies attached to, or included in, a package, an interposer, a laminate, or a die, etc. The disclosed circuit, component, or transmission line may include interconnects for broadband sub-terahertz dies, in one or more embodiments. The disclosed circuit, component, or transmission line may enable superior performance, particularly, at high frequencies, e.g., above 10 GHZ, across a wide range of frequencies, including up to and above 100 GHz. By leveraging the inherent properties of the disclosed interconnects (also referred to herein as “interconnect stages”) implemented in the disclosed circuit or component, the parasitic effects due to mismatched impedances at such interconnecting interfaces may be largely mitigated from interconnections, such as, for example, pads and solder. In other words, the disclosed circuit, component, transmission line, or interconnects eliminate(s) the need for impedance matching while consistently delivering excellent performance across a broad frequency spectrum.

In various embodiments, mismatched impedances can be removed and/or minimized in the disclosed circuit, electronic component, or transmission line by effectively splitting the interconnects in the transmission line into two identical parts separated by a quarter wavelength transmission line. In one or more embodiments, the first part of the split transmission line is placed on a first surface, for example, between the top of a laminate and the bottom of an interposer/die in a stacked layer, while the second part of the split transmission line is placed between the bottom and the top of the interposer/die. By placing two interconnects/interconnect stages a quarter wavelength apart along the transmission line at two different surfaces/layers, the periodic nature of transmission lines (with a period of half a wavelength) with two identical interconnects placed a quarter wavelength apart effectively cancels each other's parasitic effects. In one or more embodiments, the two interconnects/interconnect stages placed a quarter wavelength apart in a transmission line may have identical capacitance values yet still cancel one another's parasitic effects.

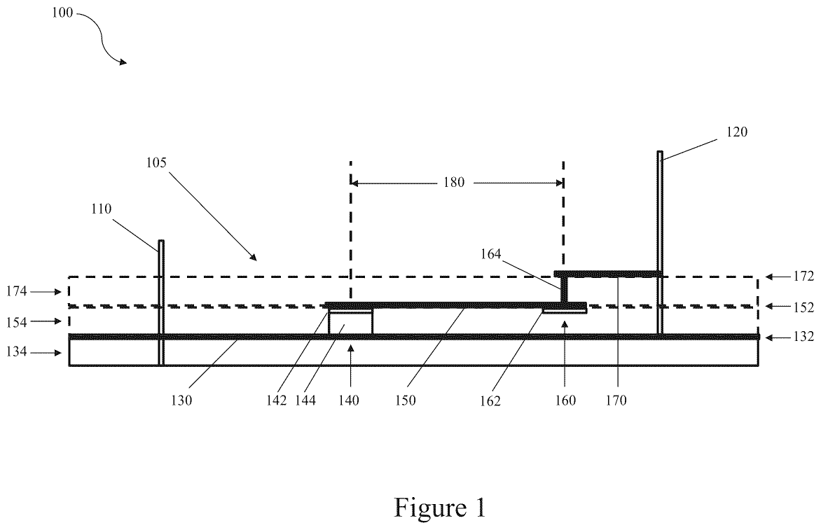

FIG. 1 illustrates an example circuit 100 comprising interconnects that are placed a quarter wavelength apart along a transmission line, according to aspects of the present disclosure. In some embodiments, the circuit 100 comprises an electronic component. Although illustrated as the circuit 100 in FIG. 1, the circuit 100 may be part of an electronic component or an electronic device, in accordance with one or more embodiments.

As illustrated in FIG. 1, the example circuit 100 includes a (signal) transmission line 105 between two ports 110 and 120. The two ports 110 and 120 may also be referred to herein as an input 110 and an output 120 or vice versa, or a first component 110 and a second component 120 or vice versa. As illustrated in FIG. 1, the signal transmission line 105 is configured to transmit a signal between two ports 110 and 120. The signal transmission line 105 includes a first transmit portion 130 coupled to a second transmit portion 150 via a first interconnect stage/interconnect 140 and the second transmit portion 150 coupled to a third transmit portion 170 via a second interconnect stage/interconnect 160. As depicted in FIG. 1, the second transmit portion 150 includes a quarter wavelength transmission line having a length that is a quarter of a wavelength of the signal being transmitted between two ports 110 and 120.

As further illustrated in FIG. 1, the first transmit portion 130, the second transmit portion 150, and the third transmit portion 170 are formed on distinct and isolated surface layers, or on different surfaces, in accordance with one or more embodiments. For example, the first transmit portion 130 is formed on a first surface layer 132, the second transmit portion 150 is formed on a second surface layer 152, which is different from the first surface layer 132, and the third transmit portion 170 is formed on a third surface layer 172, which is different from the first surface layer 132 and the second surface layer 152.

In one or more embodiments, the first interconnect stage 140 includes a contact pad 142 and the second interconnect stage 160 includes a contact pad 162. In one or more embodiments, the contact pads 142 and 162 have an identical, or substantially similar, shape and size. In one or more embodiments, the first interconnect stage 140 and the second interconnect stage 160 each have a contact pad (i.e., contact pads 142 and 162) having an identical, or substantially similar, parasitic capacitance value to one another.

In one or more embodiments, the first interconnect stage 140 also includes a vertical interconnect 144 that connects the first surface layer 132 and the second surface layer 152. In one or more embodiments, the second interconnect stage 160 includes a via hole 164 that connects the second surface layer 152 and the third surface layer 172, as shown in FIG. 1.

In one or more embodiments, the second surface layer 152 and the third surface layer 172 are surface layers of a film 174 and the via hole 164 may be formed through a thickness of the film 174. In one or more embodiments, the film 174 can include a thin film, a ceramic film, an organic film, a composite film, a laminate, silicon carbide, glass, a solder, or a combination thereof. In one or more embodiments, the second surface layer 152 and the first surface layer 132 are surface layers of a film 154, and the vertical interconnect 144 may be formed through a thickness of the film 154. In one or more embodiments, the film 154 can include a thin film, a ceramic film, an organic film, a composite film, a laminate, silicon carbide, glass, a solder, or a combination thereof. In one or more embodiments, the first surface layer 132 can be a surface layer of the film 154 or a surface layer of a film 134. In one or more embodiments, the film 134 can include a thin film, a ceramic film, an organic film, a composite film, a laminate, silicon carbide, glass, a solder, or a combination thereof.

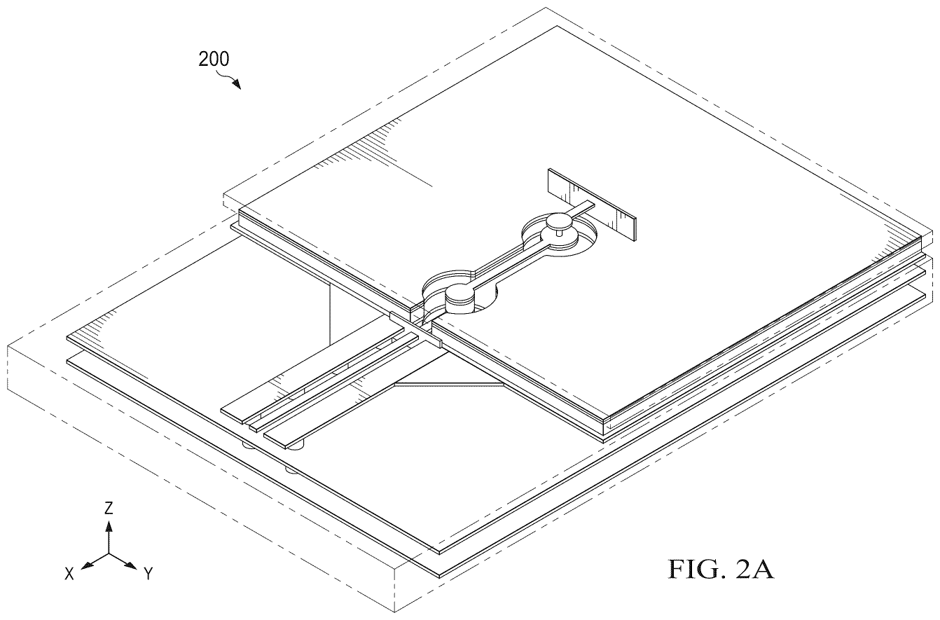

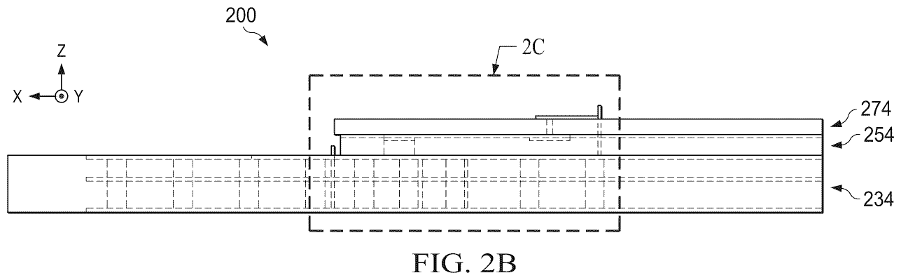

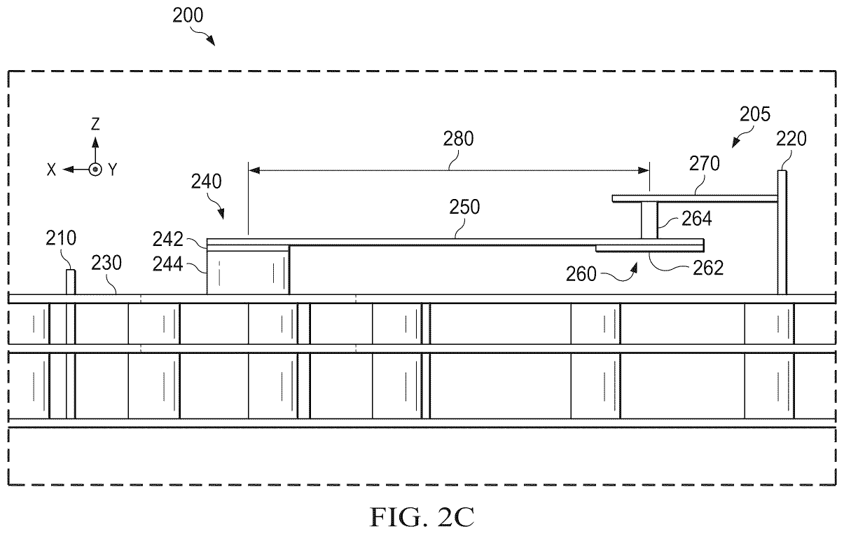

FIGS. 2A, 2B, and 2C illustrate an example circuit 200 comprising one or more interconnects, according to aspects of the present disclosure. In one or more embodiments, the circuit 200 disclosed in FIGS. 2A, 2B, and 2C may include an electronic component. Although illustrated as the circuit 200 in FIGS. 2A, 2B, and 2C, the circuit 200 may be part of an electronic component or an electronic device, in accordance with one or more embodiments.

As illustrated in FIGS. 2A, 2B, and 2C, the example circuit 200 includes a (signal) transmission line 205 between two ports 210 and 220. The two ports 210 and 220 may be referred to herein as an input 210 and an output 220 or vice versa, or a first component 210 and a second component 220 or vice versa. In various embodiments, the signal transmission line 205 includes a first transmit portion 230, a second transmit portion 250, and a third transmit portion 270, as shown in FIGS. 2A, 2B, and 2C. In one or more embodiments, the first transmit portion 230, the second transmit portion 250, and the third transmit portion 270 may be formed on distinct and isolated surface layers, or on different surfaces or different materials. In one or more embodiments, the first transmit portion 230 may be formed on a laminate or composite 234, such as for example, but not limited to, a laminate with six metallic layers. In one or more embodiments, the second transmit portion 250 may be formed on a solder 254, such as for example, but not limited to, a solder layer having a thickness of about 10 μm, about 20 μm, about 30 μm, about 40 μm, about 50 μm, or about 75 μm. In one or more embodiments, the third transmit portion 270 may be formed on a film 274, such as for example, but not limited to, a film comprising silicon carbide with a thickness of about 10 μm, about 20 μm, about 30 μm, about 40 μm, about 50 μm, or about 75 μm.

In one or more embodiments, the signal transmission line 205 may be configured to transmit a signal between two ports 210 and 220. As shown in FIGS. 2A, 2B, and 2C, the signal transmission line 205 includes the first transmit portion 230 coupled to the second transmit portion 250 via a first interconnect stage/interconnect 240 and the second transmit portion 250 coupled to the third transmit portion 270 via a second interconnect stage/interconnect 260. As depicted in FIGS. 2B and 2C, the second transmit portion 250 includes a quarter wavelength transmission line having a length that is a quarter of a wavelength of the signal being transmitted between two ports 210 and 220. The arrangement disclosed in FIGS. 2A, 2B, and 2C shows the periodic nature of transmission lines (with a period of half a wavelength) that places two identical interconnects a quarter wavelength apart to cancel each other's parasitic effects, which results in a broadband interconnect.

In one or more embodiments, the first interconnect stage 240 includes a contact pad 242 and the second interconnect stage 260 includes a contact pad 262. In one or more embodiments, the contact pads 242 and 262 have an identical, or substantially similar, shape and size. In one or more embodiments, the first interconnect stage 240 and the second interconnect stage 260 each have a contact pad (i.e., contact pads 242 and 262) having an identical, or substantially similar, parasitic capacitance value to one another.

As shown in FIGS. 2A, 2B, and 2C, the first interconnect stage 240 also includes a vertical interconnect 244 that connects the first transmit portion 230 and the second transmit portion 250. In one or more embodiments, the second interconnect stage 260 includes a via hole 264 that connects the second transmit portion 250 and the third transmit portion 270, as shown in FIGS. 2B and 2C. In one or more embodiments, the via hole 264 may be formed through a thickness of the film 274, for example, comprising silicon carbide. In one or more embodiments, the vertical interconnect 244 may be formed through a thickness of the solder 254. In one or more embodiments, the film 274 includes silicon carbide, and the via hole 264 includes a hot via, which are hollow.

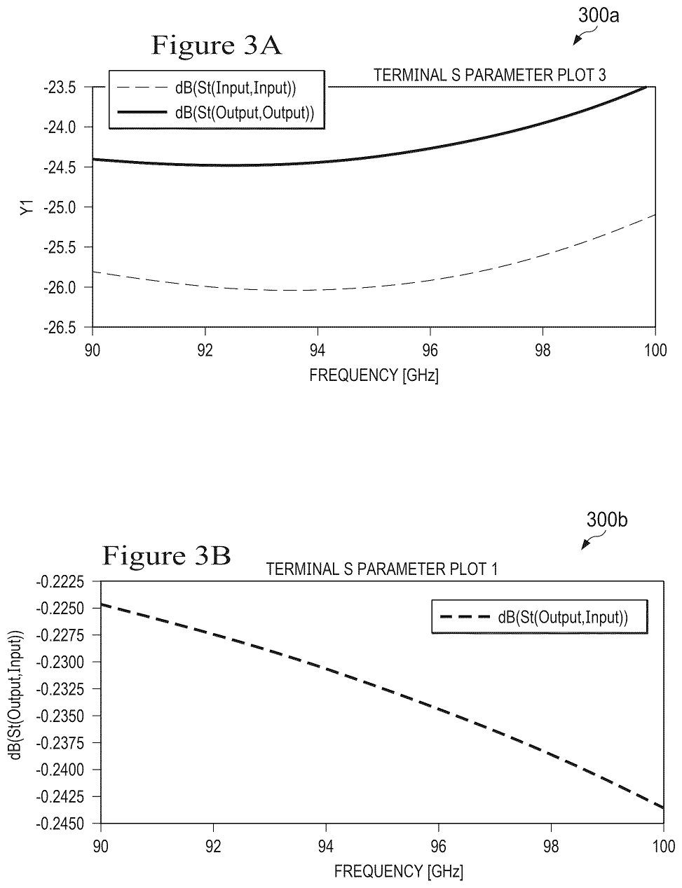

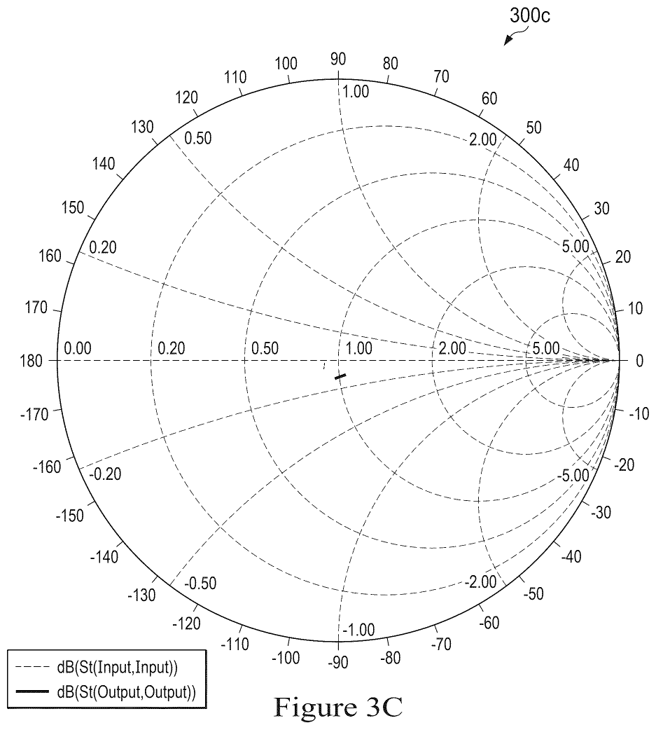

FIGS. 3A, 3B, and 3C are respective data plots 300a, 300b, and 300c showing simulation results of the circuit 200 shown in FIGS. 2A, 2B, and 2C, according to aspects of the present disclosure. The simulation of the circuit 200 aims to determine the quality of the radio frequency (RF) connection (S-parameters) of the circuit's performance. For the simulation, the laminate's top metallic layer is set to have a 50-ohm Coplanar Waveguide (CPW), and the interposer's top features a 50-ohm microstrip. The metallic connection between the CPW and the microstrip is set to include several layers: a via pad on the laminate's top, solder, a via pad on the interposer's bottom, a hot via, and a via pad on the interposer's top. Using the parameters set forth above, the simulation is performed to produce some results, which are produced as plots 300a, 300b, and 300c.

In particular, plot 300a of FIG. 3A shows a return loss of the circuit 200 from a frequency of 90 GHz to 100 GHz, whereas plot 300b of FIG. 3B shows insertion loss from 90 GHz to 100 GHz. Plot 300c of FIG. 3C shows a Smith chart with S11 (red) and S22 (green). Based on the plots 300a, 300b, and 300c, the simulation results demonstrate that the use of two interconnects/interconnect stages placed a quarter wavelength apart in a signal transmission line helps cancel parasitic effects of each other, and thus, significantly reduces parasitic effects of the overall circuit, which in turns leads to improved matching and insertion loss of the circuit.

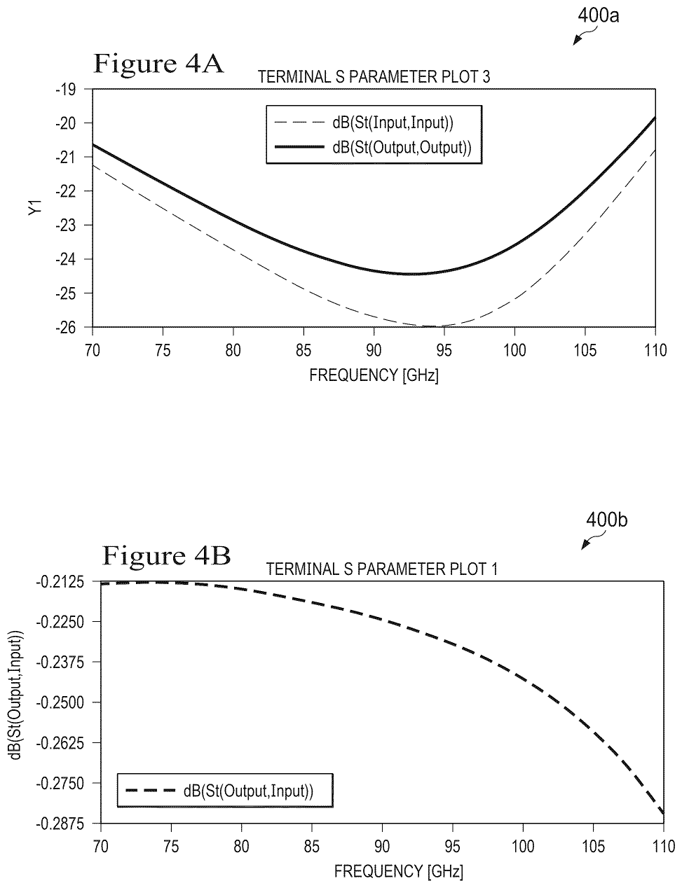

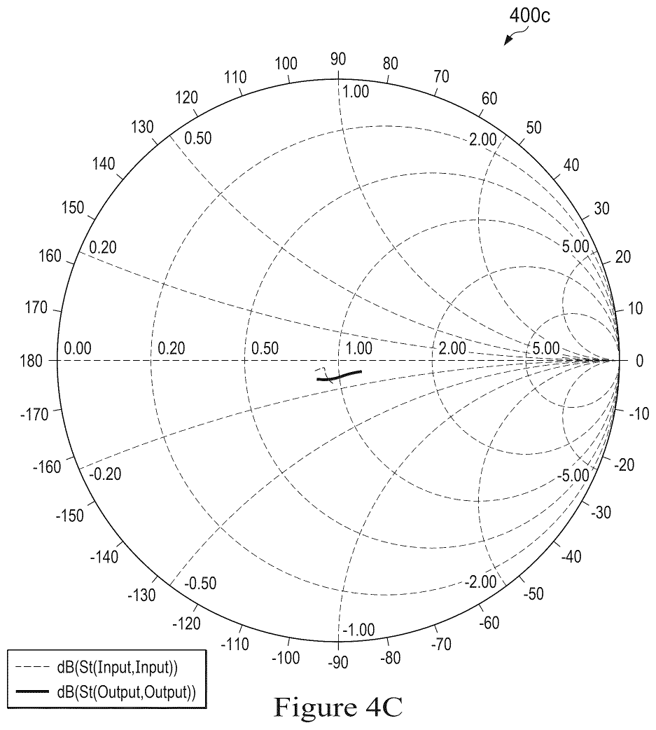

FIGS. 4A, 4B, and 4C are respective data plots 400a, 400b, and 400c showing simulation results of the circuit 200 shown in FIGS. 2A, 2B, and 2C over a broader frequency range, according to aspects of the present disclosure. Specifically, plot 400a of FIG. 4A shows a return loss of the circuit 200 from a frequency of 70 GHz to 100 GHz, whereas plot 400b of FIG. 4B shows insertion loss from 70 GHz to 100 GHz. Plot 400c of FIG. 4C shows a Smith chart with S11 (red) and S22 (green). Based on the plots 400a, 400b, and 400c, the simulation results demonstrate that the use of two interconnects/interconnect stages placed a quarter wavelength apart in a signal transmission line helps cancel parasitic effects of each other, and in addition, achieves better performance across a wide frequency range (i.e., 70 GHz to 100 GHZ), making the integration less sensitive to manufacturing and assembly tolerances.

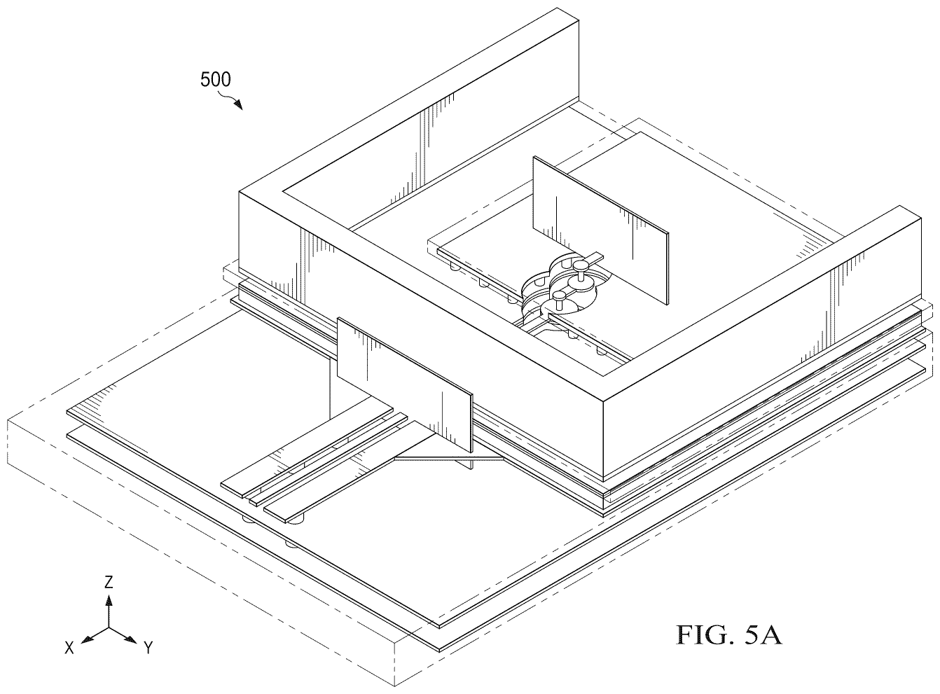

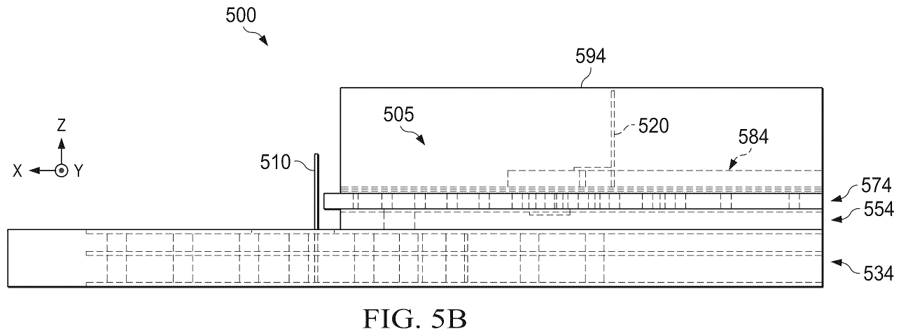

FIGS. 5A and 5B illustrate an example circuit 500 comprising one or more interconnects, according to aspects of the present disclosure. The circuit 500 described in FIGS. 5A and 5B is substantially similar to the circuit 200 as described with respect to FIGS. 2A, 2B, and 2C, and thus, like wise components and parts, such as, the signal transmission line 205, ports/components/input and output 210 and 220, laminate or composite 234, solder 254, and film 274, and other various components are identically to signal transmission line 505, ports/components/input and output 510 and 520, laminate or composite 534, solder 554, and film 574, and other various components, unless described otherwise. The differences of the circuit 500 from the circuit 200 includes an addition of a die 584, such as monolithic microwave integrated circuit (MMIC), and silicon carbide lid 594 of the circuit 500, as shown in FIG. 5B. Similar to the circuit 200, the circuit 500 disclosed in FIGS. 5A and 5B may include an electronic component or may be part of an electronic component or an electronic device, in accordance with one or more embodiments.

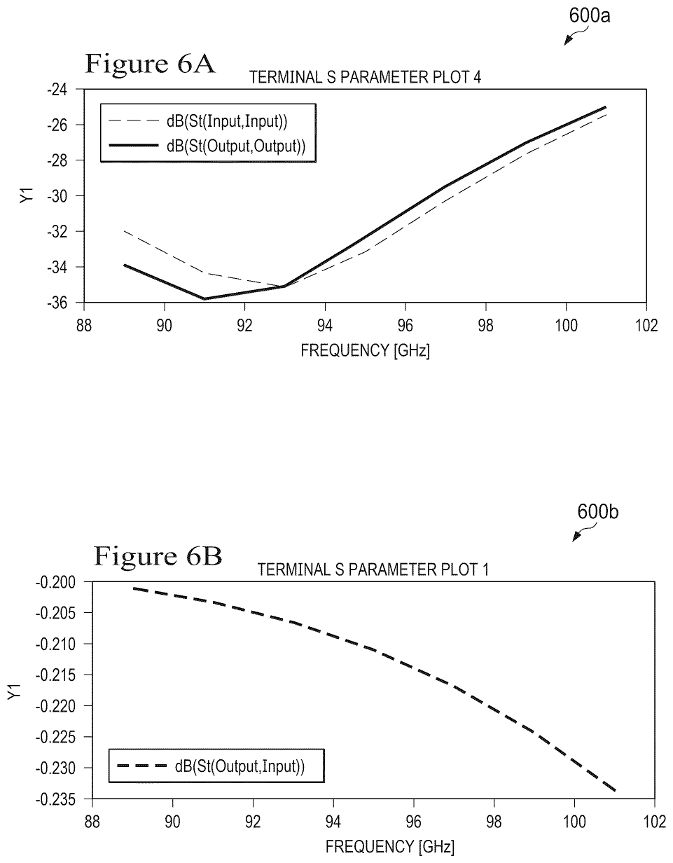

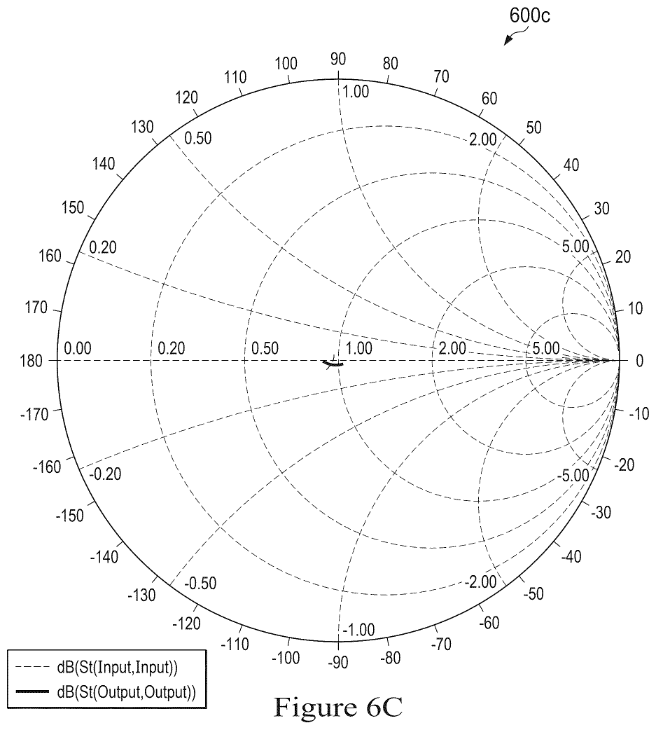

FIGS. 6A, 6B, and 6C are respective data plots 600a, 600b, and 600c showing simulation results of the circuit 500 shown in FIGS. 5A and 5B, according to aspects of the present disclosure. The simulation of the circuit 500 aims to determine the quality of the RF S-parameters of the circuit's performance. For the simulation, the laminate's top metallic layer is set to have a 50-ohm Coplanar Waveguide (CPW), and the interposer's top features a 50-ohm microstrip. The metallic connection between the CPW and the microstrip is set to include several layers: a via pad on the laminate's top, solder, a via pad on the interposer's bottom, a hot via, and a via pad on the interposer's top. Using the parameters set forth above, the simulation is performed to produce some results, which are produced as plots 600a, 600b, and 600c.

FIG. 6A includes a plot 600a showing a return loss of the circuit 600 from a frequency of 89 GHz to 101 GHZ, whereas plot 600b of FIG. 6B shows insertion loss from 89 GHz to 101 GHz. Plot 600c of FIG. 6C shows a Smith chart with S11 (red) and S22 (green). Based on the plots 600a, 600b, and 600c, the simulation results demonstrate that the use of two interconnects/interconnect stages placed a quarter wavelength apart in a signal transmission line effectively cancel all parasitic effects, achieving excellent matching and impressive insertion loss for multiple component integrations.

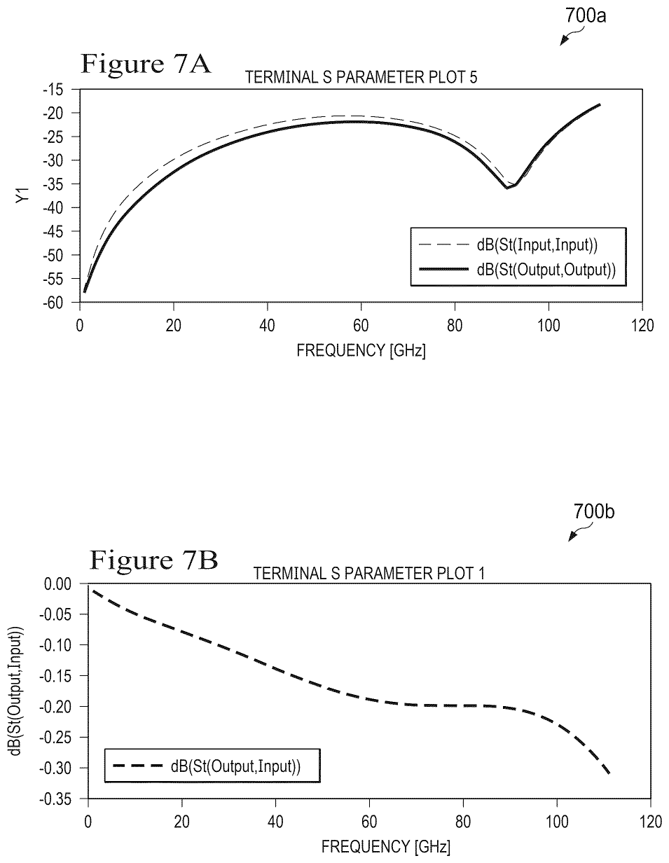

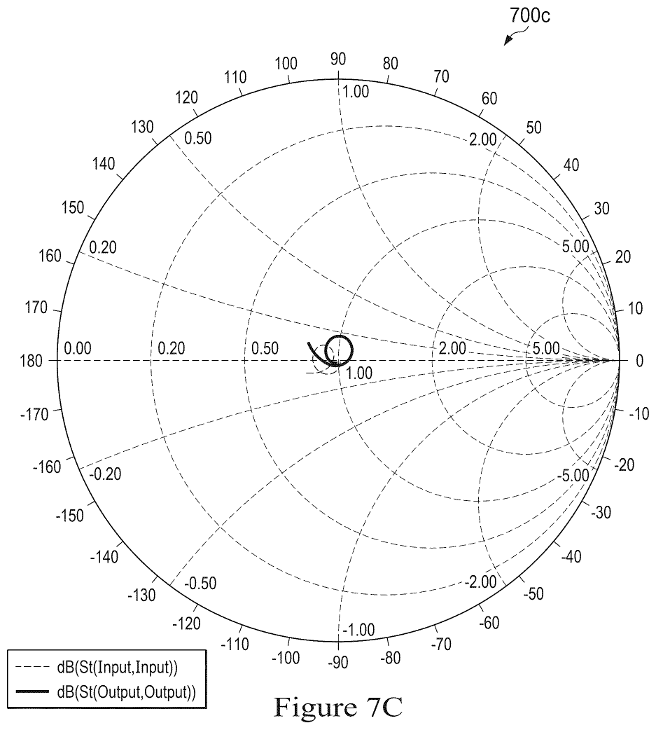

FIGS. 7A, 7B, and 7C are respective data plots 700a, 700b, and 700c showing simulation results of the circuit 500 shown in FIGS. 5A and 5B over a broader frequency range, according to aspects of the present disclosure. Specifically, plot 700a of FIG. 7A shows a return loss of the circuit 500 from a frequency of 1 GHz to 110 GHZ, whereas plot 700b of FIG. 7B shows insertion loss from 1 GHz to 110 GHz. Plot 700c of FIG. 7C shows a Smith chart with S11 (red) and S22 (green). Based on the plots 700a, 700b, and 700c, the simulation results reveal that the use of two interconnects/interconnect stages placed a quarter wavelength apart in a signal transmission line achieves remarkable matching from 1 to 105 GHz and very low insertion loss across that frequency span. This makes the integration highly resistant to manufacturing and assembly imperfections. Therefore, the disclosed method is beneficial for three-dimensional (3D) assembly of all types of semiconductors using either hot vias or TVS.

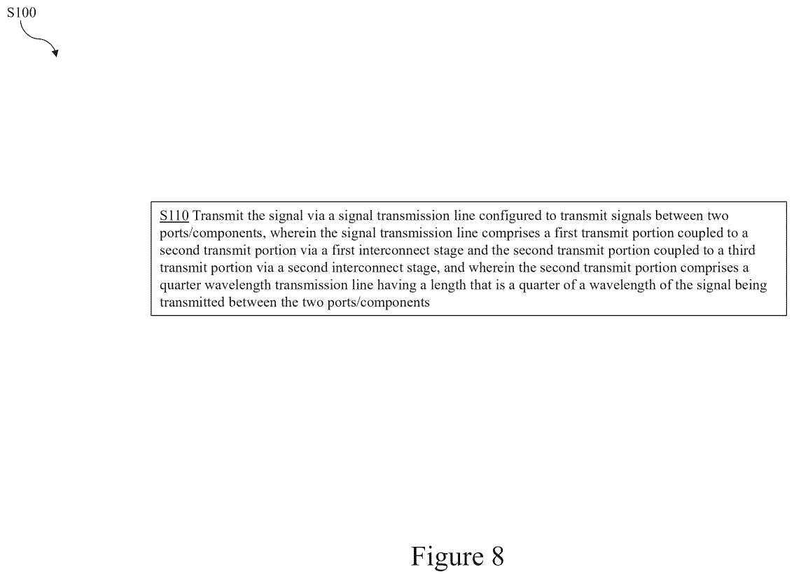

FIG. 8 illustrates a method S100 for using an example circuit, according to aspects of the present disclosure. In one or more embodiments, the example circuit may include a circuit, such as the circuits 100, 200, and 500 as described with respect to FIGS. 1, 2A, 2B, 2C, 5A and 5B. Similar to the circuits 100, 200, and 500, the example circuit includes interconnects that are placed a quarter wavelength apart along a transmission line, according to aspects of the present disclosure. In some embodiments, the example circuit may include an electronic component or may be part of an electronic component or an electronic device, in accordance with one or more embodiments.

In one or more embodiments, the method S100 may include a method for transmitting a signal using the example circuit. As shown in FIG. 8, the method S100, e.g., for transmitting a signal, includes at step S110, transmitting the signal via a signal transmission line configured to transmit signals between two ports. In one or more embodiments, the signal transmission line of the example circuit may include a signal transmission line, such as the signal transmission lines 105, 205, and 505, as described with respect to FIGS. 1, 2A, 2B, 2C, 5A and 5B. In one or more embodiments, similar to the signal transmission lines 105, 205, and 505, the signal transmission line of being used in the method S100 may include a first transmit portion coupled to a second transmit portion via a first interconnect stage and the second transmit portion coupled to a third transmit portion via a second interconnect stage, and wherein the second transmit portion comprises a quarter wavelength transmission line having a length that is a quarter of a wavelength of the signal being transmitted between the two ports.

In one or more embodiments of the method S100, the two ports may be within a circuit. In one or more embodiments, the two ports may reside on two separate circuits/electronic components and the signal transmission line may then be configured for transmitting the signal between the two separate circuits/electronic components. In one or more embodiments of the method S100, the first transmit portion, the second transmit portion, and the third transmit portion are formed on distinct and isolated surface layers, or on different surfaces. In one or more embodiments, the first interconnect stage and the second interconnect stage each comprise a contact pad having an identical, or substantially similar, parasitic capacitance value to one another.

In one or more embodiments of the method S100, the first interconnect stage may include a vertical interconnect that connects the first surface layer and the second surface layer. In one or more embodiments, the second interconnect stage may include a via hole that connects the second surface layer and the third surface layer. In one or more embodiments the method S100, the second interconnect stage is a via hole that connects the second surface layer and the third surface layer; the second surface layer and the third surface layer are surface layers of a film and the via hole is formed through a thickness of the film; and the film comprises a thin film, a ceramic film, an organic film, a composite film, a laminate, silicon carbide, glass, a solder, or a combination thereof.

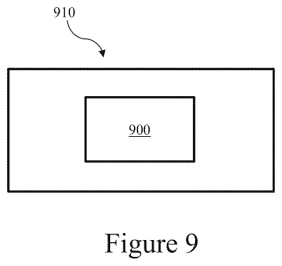

FIG. 9 illustrates an electronic or wireless device 910 comprising an example circuit 900, according to aspects of the present disclosure. In some implementations, the electronic device or wireless device 910 may include, for example, but not limited to, a computer, a cellular device, a satellite communication device, a wi-fi device, a radar, a global position system device, or any electronic device. In one or more embodiments, the circuit 900 may include a circuit, such as the circuits 100, 200, or 500, as described with respect to FIGS. 1, 2A, 2B, 2C, 5A and 5B. The circuit 900 may implement any RF circuitry used in wireless applications, as an example, such as one or more RF power amplifiers or in a radar or radar systems; and the circuit 900 may be coupled to other circuitry for implementing a wireless application, such as a baseband processor or other types of processors.

In one or more embodiments, the circuit 900 includes a signal transmission line that includes one or more interconnects (also referred to herein as interconnect stages). The signal transmission line is configured to transmit a signal between two ports (e.g., an input and an output, or a first component and a second component), the signal transmission line comprising a first transmit portion coupled to a second transmit portion via a first interconnect stage and the second transmit portion coupled to a third transmit portion via a second interconnect stage, wherein the second transmit portion comprises a quarter wavelength transmission line having a length that is a quarter of a wavelength of the signal being transmitted between the two ports.

In one or more embodiments of the circuit 900, the first transmit portion, the second transmit portion, and the third transmit portion are formed on distinct and isolated surface layers, or on different surfaces. In one or more embodiments, the first transmit portion is formed on a first surface layer, the second transmit portion is formed on a second surface layer different from the first surface layer, and the third transmit portion is formed on a third surface layer that is different from the first surface layer and the second surface layer.

In one or more embodiments, the first interconnect stage and the second interconnect stage each comprise a contact pad having identical, or substantially similar, shape and size. In one or more embodiments, the first interconnect stage and the second interconnect stage each comprise a contact pad having an identical, or substantially similar, parasitic capacitance value to one another.

In one or more embodiments of the circuit 900, the first interconnect stage includes a vertical interconnect that connects the first surface layer and the second surface layer. In one or more embodiments, the second interconnect stage includes a via hole that connects the second surface layer and the third surface layer. In one or more embodiments, the second surface layer and the third surface layer are surface layers of a film and the via hole is formed through a thickness of the film. In one or more embodiments, the film includes a thin film, a ceramic film, an organic film, a composite film, a laminate, silicon carbide, glass, a solder, or a combination thereof.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A circuit comprising:
a signal transmission line configured to transmit a signal between two ports, the signal transmission line comprising a first transmit portion coupled to a second transmit portion via a first interconnect stage and the second transmit portion coupled to a third transmit portion via a second interconnect stage,
wherein the second transmit portion comprises a quarter wavelength transmission line having a length that is a quarter of a wavelength of the signal being transmitted between the two ports.

2. The circuit of claim 1, wherein the first transmit portion, the second transmit portion, and the third transmit portion are formed on distinct and isolated surface layers, or on different surfaces.

3. The circuit of claim 1, wherein the first transmit portion is formed on a first surface layer, the second transmit portion is formed on a second surface layer different from the first surface layer, and the third transmit portion is formed on a third surface layer that is different from the first surface layer and the second surface layer.

4. The circuit of claim 1, wherein the first interconnect stage and the second interconnect stage each comprise a contact pad having identical, or substantially similar, shape and size.

5. The circuit of claim 1, wherein the first interconnect stage comprises a vertical interconnect that connects the first surface layer and the second surface layer.

6. The circuit of claim 1, wherein the second interconnect stage comprises a via hole that connects the second surface layer and the third surface layer.

7. The circuit of claim 6, wherein the second surface layer and the third surface layer are surface layers of a film and the via hole is formed through a thickness of the film.

8. The circuit of claim 7, wherein the film includes a thin film, a ceramic film, an organic film, a composite film, a laminate, silicon carbide, glass, a solder, or a combination thereof.

9. An electronic device, comprising:
a signal transmission line configured to transmit a signal between two ports, the signal transmission line comprising a first transmit portion coupled to a second transmit portion via a first contact pad and the second transmit portion coupled to a third transmit portion via a second contact pad,
wherein the first contact pad and the second contact pad have identical, or substantially similar, shape and size.

10. The electronic device of claim 9, wherein the second transmit portion comprises a quarter wavelength transmission line having a length that is a quarter of a wavelength of the signal being transmitted between the two ports.

11. The electronic device of claim 9, wherein the first transmit portion, the second transmit portion, and the third transmit portion are formed on distinct and isolated surface layers, or on different surfaces.

12. The electronic device of claim 9, wherein the first contact pad further comprises a vertical interconnect that connects the first surface layer and the second surface layer.

13. The electronic device of claim 9, wherein the second contact pad further comprises a via hole that connects the second surface layer and the third surface layer.

14. The electronic device of claim 13, wherein the second surface layer and the third surface layer are surface layers of a film and the via hole is formed through a thickness of the film.

15. The electronic device of claim 14, wherein the film includes a thin film, a ceramic film, an organic film, a composite film, a laminate, silicon carbide, glass, a solder, or a combination thereof.

16. A method for transmitting a signal, comprising:
transmitting the signal via a signal transmission line configured to transmit signals between two ports,
wherein the signal transmission line comprises a first transmit portion coupled to a second transmit portion via a first interconnect stage and the second transmit portion coupled to a third transmit portion via a second interconnect stage, and
wherein the second transmit portion comprises a quarter wavelength transmission line having a length that is a quarter of a wavelength of the signal being transmitted between the two ports.

17. The method of claim 16, wherein the two ports are within a circuit.

18. The method of claim 16, wherein the two ports reside on two separate circuits/electronic components and the signal transmission line is configured for transmitting the signal between the two separate circuits/electronic components.

19. The method of claim 16, wherein:
the first transmit portion, the second transmit portion, and the third transmit portion are formed on distinct and isolated surface layers, or on different surfaces;
the first interconnect stage and the second interconnect stage each comprise a contact pad having an identical, or substantially similar, parasitic capacitance value to one another;
the first interconnect stage comprises a vertical interconnect that connects the first surface layer and the second surface layer;
the second interconnect stage comprises a via hole that connects the second surface layer and the third surface layer; or
a combination thereof.

20. The method of claim 16, wherein:
the second interconnect stage is a via hole that connects the second surface layer and the third surface layer,
the second surface layer and the third surface layer are surface layers of a film and the via hole is formed through a thickness of the film; and
the film comprises a thin film, a ceramic film, an organic film, a composite film, a laminate, silicon carbide, glass, a solder, or a combination thereof.
